(19) United States
(12) Patent Application Publication
(10) Pub. No.: US 2009/0266701 A1
(43) Pub. Date: Oct. 29, 2009

(54) OPERATING DEVICE FOR AN ELECTRIC APPLIANCE COMPRISING CONTACT SWITCHES AND METHOD FOR SWITCHING ON A SUPPLEMENTARY HEATING DEVICE

(75) Inventor: Oliver Gremm, Sulzfeld (DE)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: E.G.O. Elektro-Geraetebau GmbH

(21) Appl. No.: 12/478,359

(22) Filed: Jun. 4, 2009

Related U.S. Application Data
(63) Continuation of application No. PCT/EP2007/010539, filed on Dec. 5, 2007.

(30) Foreign Application Priority Data
Dec. 6, 2006 (DE) 10 2006 058 873.8

(51) Int. Cl. H03K 17/975

(52) U.S. Cl. 200/600

(57) ABSTRACT

The design and evaluation of sensor elements, such as used in an electric hob, of an operating device is simplified. For this purpose, the sensor elements are configured in such a manner so as to have differently sized sub-area regions. When a finger is placed on a cover above the sensor element according to the mark provided thereon, a contact surface is created above the sensor element. By this contact surface a corresponding operating signal having variable characteristics is triggered, which can then be associated with a corresponding operating function.

### CROSS REFERENCE TO RELATED APPLICATIONS

This application is a continuation of PCT/EP2007/010539, filed Dec. 5, 2007, which in turn claims priority to DE 10 2006 058 873.8, filed on Dec. 6, 2006, the contents of both of which are incorporated by reference.

### FIELD OF THE INVENTION

The invention relates to an operating device for an electric appliance comprising contact switches, which are arranged under a cover. It also relates to a method for operating a supplementary heating device to a heating device.

### BACKGROUND OF THE INVENTION

It is known with domestic appliances, in particular hobs, which may comprise a hob plate made of, for example, glass ceramic, to provide “contact switches” under this hob plate. These contact switches may comprise capacitive sensor elements, such as are known for example from U.S. Pat. No. 5,917,165. If an operator places a finger on a point or region over the sensor element, a change in a signal may be triggered. This may be detected and interpreted as an actuation. Since the sensor elements are not conventionally visible through the cover or hob plate and so that an operator knows at which precise point to place his/her finger to trigger the operating function, visual marks such as printed signs or the like are provided on the top. In such cases, a single sensor element is conventionally provided for each different operating function, the function of said sensor element being indicated and made clear and precisely by various visual marks.

### BRIEF SUMMARY

One problem underlying the present invention is that of providing an above-stated operating device and an above-stated method with which prior art problems may be eliminated and, in particular, better use of sensor elements is possible with less complexity and more reliable functionality.

This problem is solved in one embodiment by an operating device having the features of claim 1 and a method having the features of claim 9. Advantageous and preferred configurations of the invention are the subject matter of the further claims and are explained hereinafter in greater detail. The wording of the claims is incorporated by express reference into the content of the description.

One embodiment of the invention provides that each sensor element is constructed in a “spread out” manner covering a certain area, and over each sensor element at least two marks are provided or attached, these being different marks or marks for different operating functions or for at least two sensor element functions. At least one mark is here arranged outside the center of the sensor element area. If one mark is arranged approximately over the center area or midpoint of the sensor element and the others are located away therefrom, then placing of a finger on the marks generates in each case different strength signals or signal changes at the sensor element, which may be detected for evaluation with regard to the stated sensor element function. When the finger is placed onto a mark approximately over the center of the sensor element area, the signal or the signal change is relatively large. When a finger is placed onto a mark which lies outside the center of the area, the signal or signal change is markedly smaller. This is because, inter alia, the electrical field formed over the sensor element is dependent on the area or influenced thereby. This electrical field changes, at least in the case of capacitively operating sensor elements, when a finger approaches or is placed thereon.

Thus, with a uniform evaluation method and electronics, two different operating functions or sensor element functions may be, as it were, undertaken with just one sensor element. Depending on the construction of the area of the sensor element, even more functions may be possible. This corresponds approximately to the simulation of a plurality of virtual sensor elements, which is achieved by the particular spatial arrangement of sensor element and mark relative to one another.

According to one embodiment of the invention, it is possible for a sensor element to have a substantially rectangular or circular shape, i.e., a maximally compact area, which is as it were the opposite of elongate or branched. One mark is then arranged approximately in the central region. The other mark is instead arranged relatively close to the peripheral region of the sensor element area. For example, it is arranged so close to the edge that the average contact area arising upon contact with a finger projects beyond the edge of the sensor element if contact takes place centrally on the mark. This average contact area may amount for instance to from 8 mm to 12 mm. In general, it may be stated that the absolute size ratios of the sensor element should be such that, in the case of these above-mentioned average contact areas resulting from the placing thereon of a finger, the marks are positioned in such a way, in particular those outside the center of the sensor element area, that the contact area projects over the edge of the sensor element area.

According to another embodiment of the invention, the sensor element is elongate in shape. It may then either be ensured that a mark is attached approximately in such a way above or over the sensor element that a contact area arising through contact with a finger lies wholly within the sensor area, with another mark possibly being attached in such a way that just such a contact area projects at least in part over the edge of the sensor element, or alternatively, the sensor element area may comprise sub-area regions of different sizes. Different marks are arranged over different-sized sub-area regions, it also being perfectly possible for this in each case to be concentric or over the midpoint. As a result of the different-sized sub-area regions, different-sized signals or signal changes are generated at the overall sensor element, which may be registered as in each case corresponding actuation by a drive or signal evaluating means.

In principle, it is possible to combine a plurality of different marks or mark positions with a single sensor element and thus provide a correspondingly high number of different operating functions or sensor element functions. In practice, the invention may be very effectively implemented if three or even just two different functions are provided or three or two different mark positions are provided per sensor element area. In this case, the sensor element may comprise a relatively large sub-area, which is adjoined by at least one smaller sub-area. A mark may then be arranged over the center of each sub-area. Between individual sub-areas of a sensor element a taper or narrowing shape may be provided. This is considerably narrower than the width of the small sub-areas, such that it mainly cannot contribute to the active area of the sensor element or the respective sub-area. This connection region then substantially constitutes the electrical connection between the individual sub-areas or ensures that the sensor element is electrically connected overall.

Furthermore, it is possible for a smaller sub-area to be provided for the sensor element, which is adjoined by two larger sub-areas. These may be provided in particular at opposing ends of the smaller sub-area. Here too, the smaller sub-area may be regarded as a type of drawn-out waist or narrow connection region between the two larger sub-areas. Alternatively, the smaller sub-area may in turn be connected by even narrower connections to the larger sub-areas.

The advantage of such a configuration of the invention with different-sized sub-areas or above all with the relatively narrow connection regions between small and large sub-areas consists in the fact that these narrow connections do not themselves increase the active area of a sensor element or do so only insignificantly. An operator does not therefore have to place his/her finger quite so precisely on a point or mark provided therefor as in the above-mentioned first configuration with a round or square sensor element.

Moreover, it may be intended with regard to the operating device or the operating functions performed thereby that the operating functions provided by the different marks on one and the same sensor element be complementary to one another. Examples include a type of “plus” function for increasing power or increasing a predetermined value and a “minus” function for reducing said power or said value. The advantage of providing such exactly complementary functions is that too great of an adjustment or change in one direction can be corrected merely with a slight movement of the finger. Conventionally, such sensor elements are made to be not much larger than absolutely necessary, such that the different marks are not all that far away from one another or are spaced roughly by a distance amounting to two to at most five times the diameter with an above-mentioned contact area.

For electrical connection of the sensor element or for electrical contacting, it is sufficient to provide a single connection. This may be provided at any location depending on the construction of the sensor element. Advantageously it extends, in particular in the case of sensor elements which are not optimally electrically conductive, from a region between two sub-areas.

In the case of such an operating device, the individual marks may be located still closer to one another than was hitherto conventional, since no noise margin is needed between different sensor elements. Illuminating sources may also be provided in the vicinity of the sensor element for indicating the operating state of the operating device or of the electric appliance.

It is possible with the above-stated sensor elements to activate a supplementary heating device in a novel manner to a heating device in the case of an electric appliance, which may be, for example, an oven or a hob and may comprise an above described operating device. If the heating device is started after selection by initial actuation of a minus button for power reduction, an operator thereby makes it clear that no particularly high power is desired. Experience thus shows that no supplementary heating device is required. In this case, the supplementary heating device is deactivated. If, on the other hand, the heating device is started by initial actuation of a plus button for increasing power, higher power is obviously desired. Accordingly, the supplementary heating device, which conventionally heats an even larger area than the basic heating device already present, is activated. Still further options are likewise possible, which will be described with reference to the exemplary embodiments.

These and further features of embodiments of the invention follow not only from the claims but also from the description and the drawings, the individual features being realized in each case alone or several together in the form of sub-combinations in an embodiment of the invention and in other fields and may constitute advantageous, per se protectable embodiments, for which protection is here claimed. Subdivision of the application into individual sections and intermediate headings does not limit the general applicability of the statements made thereunder.

### BRIEF DESCRIPTION OF THE DRAWINGS

Exemplary embodiments of the invention are illustrated schematically in the drawings and explained in more detail below. In the drawings:

FIGS. 1 to 4 show various sensor element constructions, which differ from one another with regard to their areal construction,

FIG. 5 shows a cross-sectional view of an operating device and

FIG. 6 shows a plan view of an operating device according to one embodiment of the invention.

### DETAILED DESCRIPTION

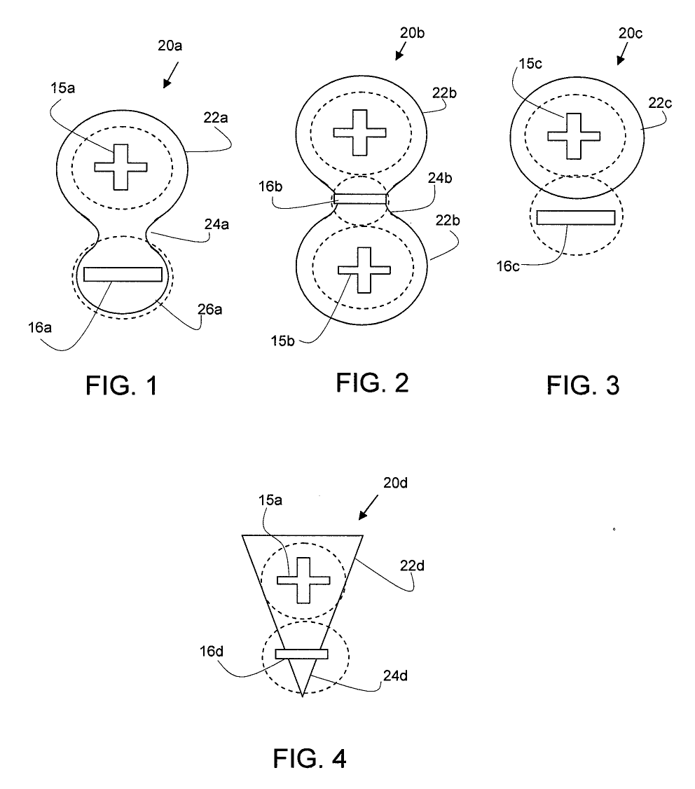

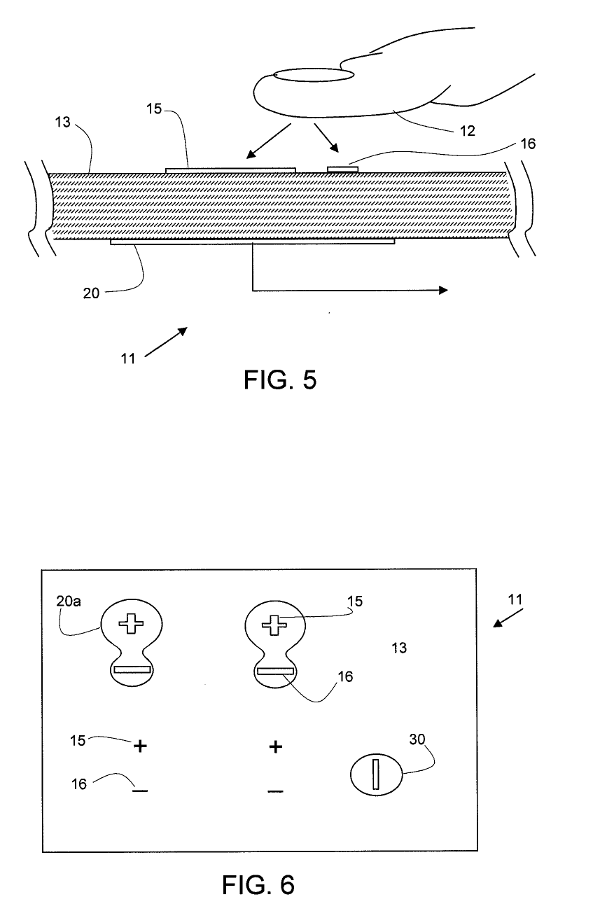

FIGS. 1 to 4 show different constructions of sensor elements 20. As FIG. 5 shows, these sensor elements 20 are mounted from below on a cover 13. The cover 13 may also be for example a hob plate of glass ceramic or the like, in the case of a hob. The sensor elements 20 are mounted from below as areas on the cover 13 or provided thereon, wherein this may proceed in a very wide range of ways. Possibilities are pressed-on areas such as flat, electrically conductive plates or laminae, films or the like. Spatially extended 3D solids may likewise be fitted to the underside of the cover 13 from below. Finally, non-removable mounting methods such as printing or the like are also possible.

Above the sensor elements 20 or on the surface of the cover 13, printed indicia or signs 15 and 16 are provided which correspond to the above-mentioned marks. These printed signs represent various symbols, as will be explained in greater detail below. A finger 12 may be placed above the sensor element 20 on the cover 13, resulting in a contact area shown by broken lines. The capacitively operating sensor element 20 registers this. Depending on the location at which the finger 12 is placed on one of the two printed signs 15 or 16 or of the contact area, a different signal arises at the sensor element 20, which will also be explained in greater detail below. Instead of slightly protruding printed signs 15 and 16, markings let in so as to be flush with the surface, recesses or even projections may also be provided. In the case of light-transmitting covers, illuminated displays arranged therebelow may also be provided. With regard to the printed signs 15 and 16 all that is important is that they constitute an operating symbol and indicate the location for operation.

When the sensor element 20a is constructed according to FIG. 1, the shape corresponds, to a certain extent, to a figure eight. A large sub-area 22a is adjoined, with a pinched-in portion or waist 24a, by a medium-sized sub-area 26a. It is clear that the large sub-area 22a is approximately three times as large as the medium-sized sub-area 26a.

Above the large sub-area 22a there is located a printed sign 15a in the form of a plus sign. Above the medium-sized sub-area 26a there is located a printed sign 16a in the form of a minus sign.

Since the sub-areas 22a and 26a, on the basis of which a finger 12 might be positioned relatively precisely in accordance with the printed signs 15a and 16a with the contact area shown by broken lines, are of different sizes, different strength signals arise in each case at the sensor element 20a.

In the case of the sensor element 20a, a further symbol could also be provided over the small sub-area 24a. By placing a finger 12 thereon, with the correspondingly resultant signal strength, operation thereof could be evaluated accordingly.

An average contact area of 8 mm to 12 mm shown by broken lines lies in the case of the upper sub-area 22a wholly within the sensor element area. In the case of the medium-sized sub-area 26a on the other hand, the average contact area shown by broken lines projects laterally therebeyond, thereby generating a smaller signal at the sensor element 20a. This would also apply to the sub-area 24a.

With regard to the size both of the small sub-area 24a and also of the medium-sized sub-area 26a, it is important that they be smaller than the typical contact area of a finger 12 on the cover 13. In this way it may be ensured that the areal coverage of the sensor element is not the maximum contact area of the finger 12, above which no greater coverage can be detected, but rather is defined by the size of the sub-area.

FIG. 2 shows a further embodiment of a sensor element 20b. Two large sub-areas 22b are connected together by way of a small sub-area 24b taking the form of a pinched-in portion. Above the large sub-areas 22b there are located printed signs 15b in the form of plus signs. Above the small sub-area 24b there is located a printed sign 16b in the form of a minus sign. With this sensor element 20b, it is possible, in the context of a novel operating philosophy, to actuate a plus sign with the same operating function at two different locations.

FIG. 3 shows a further variant of a sensor element 20c, which differs somewhat from those described above. In this case, just a single large area 22c is present. Over the center of this area 22c there is located a printed sign 15c in the form of a plus sign and therebelow, close to the peripheral area, a printed sign 16c in the form of a minus sign.

If a finger 12 is placed over the printed sign 15c, areal coverage is obtained over the complete contact area of the finger 12 shown by the upper broken lines, which corresponds to a large signal. If the finger 12 is placed on the lower printed sign 16c, it covers the sensor element 20c with only part of its contact area. This gives rise to a small signal or a signal which is in any case is smaller than that obtained when the finger is placed on the upper printed sign 15c.

In this way, it is possible even with such a sensor element 20c, which is not subdivided into sub-areas, for differently positioned actuations or contact areas to be identified as different. In this case it is also possible, by mounting printed signs or marks at different proximities to the edge, to bring about different positioning locations and different areal coverages and thus different signal strengths. However care must be taken to ensure that such differentiation is still possible even in the case of not quite precisely effected actuation. In the case of such a round or compact areal, for example square, construction of the sensor element 20, advantageously only two different positioning locations for two different actuations are provided.

FIG. 4 shows a sensor element 20d whose shape corresponds approximately to an upended narrow triangle with a wide, large upper sub-area 22d and an adjoining narrow, small lower sub-area 24d. Above the large sub-area 22d there is located a printed sign 15d in the form of a plus sign. Above the small sub-area 24d there is located a further printed sign 16d in the form of a minus sign.

### Function

In simple terms, a large signal at the sensor element 20 is evaluated as corresponding to the placing of a finger 12 on a large sub-area or to a large contact area. A medium-sized signal is evaluated as corresponding to the placing of a finger 12 on a medium-sized sub-area. A small signal is evaluated as corresponding to the placing of a finger 12 on a small sub-area 24. The contact areas provided or arising on placing of the finger are shown by broken lines.

It should be noted that the sensor element 20 can only detect different signal strengths, i.e., it does not directly detect a location-dependent positioning of a finger. For evaluation purposes, it is assumed that a positioned finger 12 represents a more or less always identical contact area and thus a more or less always identical capacitive coupling to the sensor element 20. Were the finger 12 to be placed at the edge of a large sub-area 22 in such a way that it covers this only with an area which corresponds to a small or a medium-sized sub-area, a corresponding small or medium-sized signal would be present at the sensor element 20. This would then be evaluated by the sensor element 20 as the placing of the finger on a small or medium-sized sub-area, which would give rise to an altogether incorrect evaluation.

This may be prevented by explaining explicitly to an operator in the operating instructions that a finger must be placed relatively precisely on one of the printed signs or symbols. Only in this way is an association possible between correct finger-placing and a correctly derived operating signal.

### Illustration of the Operating Device

FIGS. 5 and 6 show an operating device 11. Under a cover 13 there are provided, in addition to an on-off switch 30, which may also take the form of a sensor element, four sensor elements 20 corresponding to FIG. 1. In this case, the printed signs 15 and 16 are provided on the top of the cover 13. The broken-line representation of the sensor elements 20 in FIG. 6 makes it clear that they are invisible to an operator, since they lie under the cover 13. At the bottom of the operating device 11 in FIG. 6 the broken-line representation of the sensor element has in each case been omitted, so that it may be better shown how the operating device 11 looks to an operator with regard to the sensor elements 20 and the printed signs 15 and 16.

In itself, operation for example of a hob with the operating device 11 otherwise corresponds to conventional operating methods. After switching on using the on-off switch 30, power is increased or another function selected for a corresponding heating unit by operation through placing the finger 12 on one of the printed signs 15 or 16. There may be a local relationship between the arrangement of the heating unit on the hob and the arrangement of the printed signs.

1. An operating device for an electric appliance has contact switches and a cover over said contact switches, said contact switches comprising capacitive sensor elements, wherein visually visible marks are provided for an operator on said cover over said sensor elements, so as to indicate a contact position provided for triggering said operating function symbolized by said mark by applying a finger on said mark, wherein said sensor element is constructed in a spread out manner covering an area, wherein at least two said visible marks are arranged over each said sensor element for at least two sensor element functions, at least one said mark being arranged outside a center of said area of said sensor element.

2. The operating device as claimed in claim 1, wherein at least one said sensor element is a capacitive sensor element and has a substantially rectangular or circular shape, wherein one said mark is arranged approximately in a central region of said area of said sensor element and another said mark is arranged close to a peripheral region of said area of said sensor element.

3. The operating device as claimed in claim 1, wherein at least one said sensor element is a capacitive sensor element and has an elongate shape with different-sized sub-area regions, wherein in each case different said marks are arranged over said different-sized sub-area regions of said sensor element for generating different-sized sensor element signals when said mark is contacted with a finger for said respective sensor element function.

4. The operating device as claimed in claim 3, wherein one said sensor element of said contact switch is constructed for two different sensor element functions and comprises two types of said mark, said sensor element comprising a larger said sub-area region adjoined by at least one said smaller sub-area region and said mark being arranged approximately over said center of each said sub-area.

5. The operating device as claimed in claim 3, wherein a waist is provided between said individual sub-area regions of said sensor element, wherein said waist is narrower than a largest width of a smallest sub-area region.

6. The operating device as claimed in claim 3, wherein a smaller sub-area region of a sensor element is adjoined by two larger sub-area regions.

7. The operating device as claimed in claim 6, wherein said smaller sub-area region takes the form of a waist area between said larger sub-areas.

8. The operating device as claimed in claim 1, wherein operating functions of said different marks on one sensor element are mutually complementary comprising s a plus function for increasing power and a minus function for reducing said power.

9. A method for activating a supplementary heating device to a heating device in an electric appliance comprising a hob wherein said operating device comprises contact switches and a cover over said contact switches, said contact switches comprising capacitive sensor elements, wherein visually visible marks are provided for an operator on said cover over said sensor elements, so as to indicate a contact position provided for triggering said operating function symbolized by said mark by applying a finger on said mark, wherein said sensor element is constructed in a spread out manner covering an area, wherein at least two said visible marks are arranged over each said sensor element for at least two sensor element functions, at least one said mark being arranged outside a center of said area of said sensor element, wherein said supplementary heating device is deactivated if said heating device is started by initial actuation of a minus button for power reduction and is activated if said heating device is started by contacting of a plus button for increasing power.

10. An electric appliance comprising:
a cover having a first side facing a user and a second side facing away from a user, said cover configured to be touched by a user's finger thereby defining a touch area wherein said user's finger contacts said cover;
a first visible indicia and a second visible indicia on said first side of said cover, said first and second visible indicia indicating a first and a second contact position for placement of said user's finger to trigger an operating function of said electric appliance, wherein said first visible indicia and said second visible indicia symbolize complementary inputs associated with said operating function; and
at least one capacitive contact switch comprising a sensor element attached to said second side of said cover,
said sensor element having a symmetrical shape having a first sub-area wherein a central point of said first sub-area is located underneath said first visible indicia,
said first sub-area having a first area greater than said touch area of said user's finger,
said sensor element having a second sub-area wherein a central point of the second sub-area is located underneath said second visible mark, and
wherein said second sub-area has a second area that is smaller than said touch area.

11. The electrical appliance of claim 10 wherein the sensor element has a curvi-linear shape comprising said first sub-area having a first partially circular shape and said second sub-area comprising a second partially circular shape, wherein the first partially circular shape is larger than said second partially circular shape.

12. The electrical appliance of claim 11 further comprising a heating element, wherein said electrical appliance is a hob, and said first sub-area is configured to generate a first signal when touched by said user's finger during operation of said electrical appliance that increases power to said heating element and said second sub-area is configured to generated a second signal when touched by said user's finger during operation of said electrical appliance that decreases power to said heating element.
